(19) United States
(12) Patent Application Publication
(10) Pub. No.: US 2002/0121707 A1
(43) Pub. Date: Sep. 5, 2002

(54) Super-thin high speed flip chip package

(75) Inventors: Rajendra Pendse, Fremont, CA (US); Samuel Tam, Daly City, CA (US)

Correspondence Address: HAYNES BEFFEL & WOLFELD LLP, P O BOX 366, HALF MOON BAY, CA, 94019, US

(73) Assignee: ChipPAC, Inc., Fremont, CA (US)

(21) Appl. No.: 10/084,787

(22) Filed: Feb. 25, 2002

Related U.S. Application Data
(60) Provisional application No. 60/272,236, filed on Feb. 27, 2001.

(51) Int. Cl. H01L 21/44

(52) U.S. Cl. 257/778; 438/108

(57) ABSTRACT

A chip package achieves miniaturization and excellent high-speed operation by employing flip chip interconnection between the die and the package substrate, and mounting the chip on the same side of the package substrate as the solder balls for the second level interconnection to the printed circuit board. Also, two-die packages have a first die attached to the same surface as the second level interconnect structures and connected using flip chip interconnection, and a second die connected to the opposite surface of the substrate and interconnected either by wire bonding or by flip chip interconnection.

### CROSS REFERENCE TO RELATED APPLICATION

This application claims priority from Provisional Application No. 60/272,236, filed Feb. 27, 2001.

### BACKGROUND

This invention relates to chip scale semiconductor device packaging.

Chip packages for housing integrated circuit die are in increasing demand in applications such as hand-held or portable electronics and in miniaturized storage devices such as disk drives. In many such applications there is a need for such packages to operate at very high frequencies, typically in excess of 1 GHz, to fulfill the needs of analog or RF devices and of fast memories used in cellular phones.

So-called “chip scale packages” are in common use in such applications. Chip scale packages conventionally employ wire bonding as the means for interconnection between the integrated circuit die and the substrate. It is desirable to minimize the thickness of chip scale packages, to the extent practicable. Chip scale packages with wire bond interconnect having an overall package height in the range of 0.6-0.8 mm have been produced.

Further reduction of package thickness is increasingly difficult, owing primarily to two factors. First, wire bonding interconnection employs wire loops of finite height (imposing lower limits on size in the “Z” direction) and span (imposing lower limits on size in the “X” and “Y” directions), running from bond pads at the upper surface of the die, up and then across and down to bond sites on the upper surface of the substrate onto which the die is attached. The loops are then enclosed with a protective encapsulating material. The wire loops and encapsulation typically contribute about 0.2-0.4 mm to the package thickness. Second, as these packages are made thinner, the “second level interconnections” between the package and the printed circuit board are less reliable. In particular, second level interconnections that lie under the “shadow” of the die are most adversely affected.

Moreover, improvement of electrical performance presents significant challenges, for at least two reasons. First, it is difficult to reduce the signal path length, because the wire bonds themselves typically have a typical length about 1.0 mm. Second, the structure of the package necessitates “wrap-around” routing of conductive traces; that is, the traces have to fan outward to vias, and then run back inward to the solder ball locations.

A package structure is desired that circumvents the above obstacles and provides for further package miniaturization and improved high-speed operation.

### SUMMARY

According to the invention, a chip package achieves miniaturization and excellent high-speed operation by employing flip chip interconnection between the die and the package substrate, and mounting the chip on the same side of the package substrate as the solder balls for the second level interconnection to the printed circuit board.

Accordingly, in one general aspect the invention features a chip scale integrated circuit chip package including a die mounted by flip chip interconnection to a first surface of a package substrate, and having second level interconnections formed on the first surface of the package substrate. The die is provided with interconnection bumps affixed to an arrangement of connection sites in a first surface of the die, and the flip chip interconnection is made by apposing the first surface of the die with the first surface of the package substrate and bringing the interconnect bumps into contact with a complementary arrangement of interconnect pads on the first surface of the substrate under conditions that promote bonding of the bumps on the pads.

According to the invention, the interconnect bumps provide a thin gap between the die and the substrate, and this gap may be at least partly filled with a die attach material (such as a die attach epoxy). The combined thickness of the die and the gap is less than the gap provided by the solder ball interconnections between the substrate and the printed circuit board, so that the effective die thickness is accommodated within the second level interconnect gap, and contributes nothing to the overall package thickness (“Z” direction miniaturization).

Moreover, because according to the invention there are no wire bonds connecting this first die to the substrate, the need to accommodate a wire bond span is eliminated, permitting miniaturization in the “X” and “Y” directions as well.

In some embodiments the connection of the interconnect bumps and the pads is a solid state connection, made by applying heat and mechanical force to deform the bumps against the pads without melting either mating surface. Such solid state bonds can provide for finer interconnect geometries than can be obtained using melt-bond connection.

In some embodiments the die is attached at about the center of the substrate, and the solder balls for the second level interconnections are located nearer the periphery of the substrate.

In such embodiments there are no second level connection solder balls in the shadow of the die, so that the second level interconnect reliability can be superior to that of conventional ship scale packages in which there are solder balls under the shadow of the die.

In some embodiments the electrical traces are formed within an interconnect layer in the first surface of the package substrate, and the traces fan outward from the interconnect pads to the solder ball attachment sites.

In such embodiments the signal path is minimized by significant reduction of total trace lengths, both by elimination of wire bonds and by elimination of wraparound routing of traces.

In some such embodiments a ground plane is optionally provided on the second surface of the substrate, and connected to the second level interconnect balls and/or to the interconnect traces through one or more vias in the substrate. Such a ground plane need not be provided with any “keep out” areas, and can be an uninterrupted ground plane structure over the entire second surface. Such a ground plane configuration can provide superior electrical performance, approaching that of micro strip transmission lines.

In some embodiments at least some of the traces are constructed as coplanar waveguides, in which ground lines are formed to run alongside the signal line on a planar dielectric material.

In other embodiments, a second die is attached to the substrate, on the surface opposite the first one, and is connected through vias to the second level interconnects and/or to the first die traces. The second die may be attached by conventional wire bonding. This makes a package having about the same thickness as a conventionally constructed wire-bond chip scale package, but which according to the invention includes the first die, carried on the same surface of the substrate as the second level solder balls in addition to the wire-bonded die. That is, a package having two chips can according to this aspect of the invention be accommodated within an overall package height approximately the same as that of the conventional wire bonded chip package having only a single die. Or, the second die may be attached by a flip-chip interconnect. Because the flip chip configuration can be made with less height than the wire bond configuration, this embodiment provides a still thinner two-die package.

### BRIEF DESCRIPTION OF THE DRAWINGS

FIG. 1 is a diagrammatic sketch in a sectional view of a conventional chip scale package having wire bond interconnection.

FIG. 2 is a diagrammatic sketch in a sectional view of an embodiment of a thin high speed chip scale package according to the invention.

FIG. 3 is a diagrammatic sketch in a sectional view of another embodiment of a thin high speed chip scale package according to the invention.

FIG. 4 is a diagrammatic sketch in a sectional view of still another embodiment of a thin high speed chip scale package according to the invention.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGS. illustrating embodiments of the invention, elements corresponding to elements shown in other drawings are not all particularly renumbered, although they are all readily identifiable in all the FIGS. Also for improved clarity, certain details, not necessary to understanding the invention, are not particularly illustrated in the drawings.

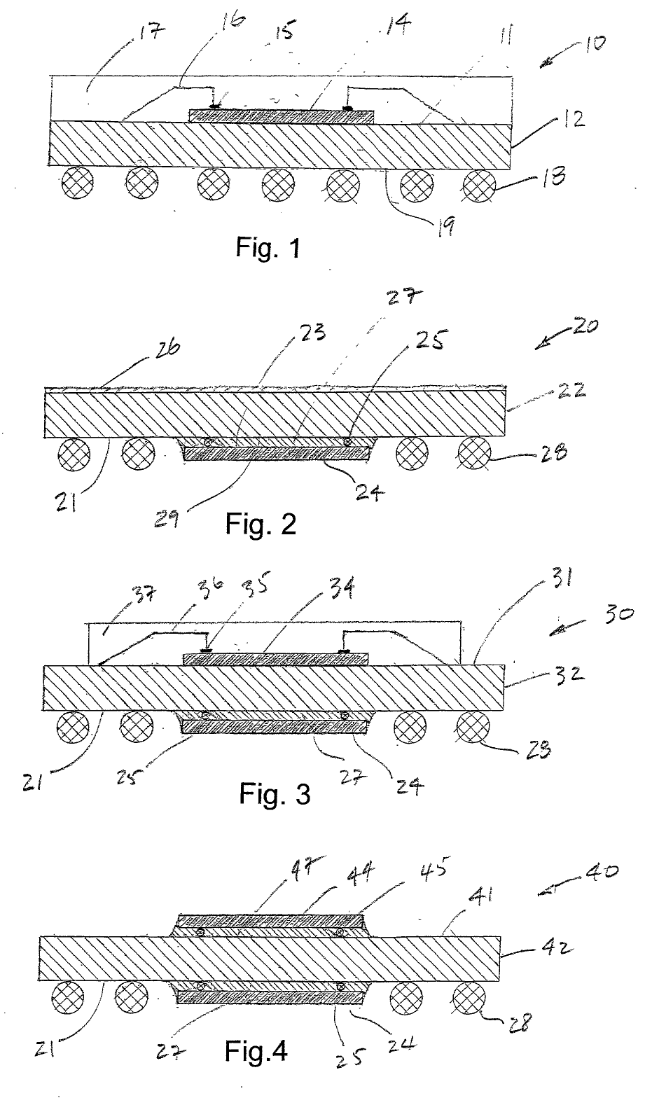

Turning now to FIG. 1, there is shown in a diagrammatic sectional view a conventional chip scale package generally at 10, including a die 14, attached to a surface 11 of a package substrate 12. The die 14 is electrically connected to the package substrate 12 by way of wire bonds 16 connected to wire bond pads 15 on the die 14 and to interconnect sites in the surface 11 of the substrate 12. The die, the wire bonds, and the upper surface 11 of the substrate 12 are enclosed within and protected by a molded plastic encapsulation material 17. A set of second level interconnect balls 18 are attached to sites on a surface 19 of the substrate 12 opposite the surface 11 on which the die is attached. As will be understood, the substrate, referred to as 12 in FIG. 1, includes a number of features not shown in the FIGS. ; particularly, for example, electrical connection structures (electrical traces) are conventionally provided at or near the surface 11 and the surface 19 for connection with the wire bonds from the die and with the solder balls, respectively, and vias running through the thickness of the substrate serve to electrically interconnect features on the top and on the bottom of the substrate.

Turning now to FIG. 2, an embodiment of a chip scale package according to the invention is shown generally at 20. Here, the package substrate 22 is provided on a first (“lower”) surface 21 with a set of second level interconnect solder balls 28. In this embodiment, these second level solder balls are arranged near the periphery of the substrate. According to the invention, the die 24 is affixed to a die attach region 29 on the first (“lower”) surface 21 of the package substrate using a die attach material 27, typically a die attach epoxy. Interconnection between the die and the substrate is made by way of interconnect bumps 25. Flip chip interconnection is known; usually the interconnect bumps 25 are attached to interconnect sites in an arrangement on conductive traces (not shown in the FIGS. ) in or near the surface 23 of the die, and these interconnect bumps are then bonded to connection sites in a complementary arrangement (not shown in the FIGS. ) on conductive traces in or on the substrate. Preferably, the interconnect bumps 25 are bonded to their respective pads in a solid-state fashion; that is, the bumps are thermo-mechanically connected to the pads by concurrently forcing the bonds against the pads and applying sufficient heat to deform the bonds against the pads without melting either the bond material or the pad material. Such solid state interconnect can provide for interconnect geometries in ranges less than about 0.1 mm pitch.

The dimensions of the various features can be selected to minimize the overall thickness of the package. For example, the bump structures and interconnection means can be designed so that the gap between the die surface 23 and the die attach surface of the substrate 29 is less than about 0.025 mm. Because the die in this embodiment is carried on the lower surface of the substrate, and because its thickness is accommodated within the gap between the lower surface of the substrate and the underlying integrated circuit, as limited by the size of the second level interconnect balls 28, the overall package is thinner in this embodiment by an amount corresponding to about the thickness of the wire bonded die and its encapsulation, as illustrated for example in FIG. 1. Moreover, because the second level interconnect structures are located near the periphery of the substrate, the second level reliability is superior to that obtainable where there are there are solder balls situated in the shadow of the die.

Optionally, although not necessarily, a ground plane 26 may be provided as a more or less continual electrically conductive sheet (for example, a metal such as copper) substantially covering the upper surface of the substrate 22. One or more vias passing through the substrate (not shown in the FIG. ) can be formed to connect the ground plane to appropriate second level solder balls (“ground balls”) at the surface 21 of the substrate.

Advantageously, the conductive traces running from the connection sites in the surface 21 of the substrate can according to the invention run directly to assigned solder ball connection sites. In some embodiments these conductive traces are formed as coplanar waveguides, which structures are known.

In a typical embodiment, the thickness of the package substrate is approximately 0.1 mm, the height of the solder balls measured from the substrate surface is approximately 0.3 mm, and the height of the die is approximately 0.18 mm; this gives an overall package height of approximately 0.4 mm. Further reductions in these dimensions are possible, so that overall package heights les than 0.4 mm can be obtained according to the invention.

Moreover, the length of the longest conductive traces can be less that 1.0 mm in an embodiment having to peripherally arranged rows of solder balls at a 0.5 mm pitch. This can provide exceptionally high electrical performance.

FIGS. 3 and 4 show, at 30 and at 40, alternative embodiments of the invention in which the package includes a first die attached by flip chip interconnection to the same (“lower”) surface of the substrate as the second level interconnect structures, generally as described with reference to FIG. 2; and a second die affixed to the second (“upper”) surface of the package substrate. In FIG. 3 the second die is interconnected to the substrate using conventional wire bonds, and in FIG. 4 the second die is interconnected to the substrate by flip-chip interconnection.

In FIG. 3, the first die 24 is affixed using a die attach material 27 onto a central die attach region of the first (“lower”) surface 21 of the substrate 32, and interconnect is made by way of interconnect bumps 25; and second level interconnect balls 28 are attached to the first surface 21 near the periphery of the substrate as described with reference to FIG. 2. A second die 34 is attached on the opposite (“upper”) surface 31 of the substrate 32 and is electrically connected to the package substrate by way of wire bonds 36 connected to wire bond pads 35 on the die 34 and to interconnect sites in the surface 31 of the substrate 32. The dies and associated wire bonds are enclosed in and protected by encapsulation material 37. Features on or in the upper surface are electrically connected to features on or in the lower surface through vias (not shown in the FIGS. ) running through the substrate.

The dimensions of the second die and associated structures in the embodiment of FIG. 3 can be made similar to the dimensions of the die 14 and associated structures in the conventional package as shown in FIG. 1. Accordingly the overall package height of the package according to the invention as illustrated in FIG. 3 can be made similar to that in the conventional package, but in the embodiment of FIG. 3 the package is a two-die package, and it is a two-die package in which the first die 24 has superior electrical properties, as described above with reference to FIG. 2.

A still thinner overall two-die package, in which the second die can also have superior electrical performance, can be constructed as shown at 40 in FIG. 4. Here, as in the embodiment of FIG. 3, the first die 24 is affixed using a die attach material 27 onto a central die attach region of the first (“lower”) surface 21 of the substrate 32, and interconnect is made by way of interconnect bumps 25; and second level interconnect balls 28 are attached to the first surface 21 near the periphery of the substrate as described with reference to FIG. 2. In this embodiment, however, the second die is electrically connected to the substrate using a flip chip interconnect. That is, die 44 is affixed using a die attach material 47 to a second die attach region on the second (“upper”) surface 41 of the substrate 42, and is interconnected to the substrate by way of interconnect bumps 45. As in the embodiment of FIG. 3, features on or in the upper surface are electrically connected to features on or in the lower surface through vias (not shown in the FIGS. ) running through the substrate. This package can be still thinner than one constructed as in FIG. 3, because the die and flip chip interconnect can itself be thinner than a die and wire bond interconnect.

Other embodiments are within the following claims.

What is claimed is:

1. A chip scale integrated circuit chip package comprises a die mounted by flip chip interconnection to a first surface of a package substrate, and second level interconnections formed on the first surface of the package substrate.

2. The package of claim 1 wherein the die is provided with interconnection bumps affixed to an arrangement of connection sites in a first surface of the die, and the flip chip interconnection is made by apposing the first surface of the die with the first surface of the package substrate and bringing the interconnect bumps into contact with a complementary arrangement of interconnect pads on the first surface of the substrate under conditions that promote bonding of the bumps on the pads.

3. The package of claim 1 wherein a gap between the first surface of the die and the first surface of the substrate is at least partly filled with a die attach material.

4. The package of claim 1 wherein the height of the second level interconnections defines a standoff, and the sum of a thickness of the first die and a gap between the first surface of the die and the first surface of the substrate is less than the standoff.

5. The package of claim 1 wherein the connection of the interconnect bumps and the pads is a solid state connection, made by applying heat and mechanical force to deform the bumps against the pads without melting either mating surface.

6. The package of claim 1 wherein the first die is attached at about the center of the first surface of the substrate, and the solder balls for the second level interconnections are located nearer the periphery of the substrate.

7. The package of claim 1 wherein a ground plane is optionally provided on the second surface of the substrate.

8. The package of claim 1 wherein at least some electrical traces are constructed as coplanar waveguides.

9. The package of claim 1, further comprising a second die attached to a second surface of the substrate.

10. The package of claim 9 wherein the second die is interconnected to the substrate by wire bonding.

11. The package of claim 9 wherein the second die is interconnected to the substrate by a flip-chip interconnect.
